(19) United States
(12) Patent Application Publication
(10) Pub. No.: US 2021/0397772 A1
(43) Pub. Date: Dec. 23, 2021

(54) QUANTUM CIRCUIT SIMULATION METHOD AND DEVICE, APPARATUS, AND STORAGE MEDIUM

(71) Applicant: Beijing Baidu Netcom Science and Technology Co., Ltd., Beijing (CN)

(72) Inventors: Shusen Liu, Beijing (CN); Runyao Duan, Beijing (CN); Ningfeng Wang, Beijing (CN); Danxiang Wu, Beijing (CN)

(21) Appl. No.: 17/132,929

(22) Filed: Dec. 23, 2020

(30) Foreign Application Priority Data
Jun. 23, 2020 (CN) 202010580060.0

(51) Int. Cl. G06F 30/3308; G06N 10/00

(52) U.S. Cl. CPC G06F 30/3308; G06N 10/00

(57) ABSTRACT

A quantum circuit simulation method and device, an apparatus, and a storage medium are provided, which are related to a field of quantum simulation computation. The specific implementation is: obtaining, based on a quantum circuit containing n qubits, an n-order pure state corresponding to the quantum circuit; determining, based on the quantum circuit, a (k, k)-order gate tensor representing a quantum gate, on which a contraction processing is to be performed with the n-order state tensor; transforming the contraction processing between the n-order state tensor and the (k, k)-order gate tensor into a processing between matrices which can be expressed in a classic computer and reduce a computation amount in the classic computer, to obtain a processing result; and using the processing result as a result of the contraction processing between the n-order state tensor and the (k, k)-order gate tensor, to complete simulation of the quantum circuit.

### CROSS-REFERENCE TO RELATED APPLICATIONS

This application claims priority to Chinese patent application, No. 202010580060.0, entitled “Quantum Circuit Simulation Method and Device, Apparatus, and Storage Medium”, filed with the Chinese Patent Office on Jun. 23, 2020, which is hereby incorporated by reference in its entirety.

### TECHNICAL FIELD

The present application relates to a field of quantum computer technology, in particular, to a field of quantum simulation computation.

### BACKGROUND

A tensor network is one of mathematical tools playing a central role in fields of modern physics and computer science research. D. Deutsch established in 1989 a quantum computational model and revealed that a quantum circuit is a type of tensor network, and the essence of a quantum circuit computation process lies in tensor network contraction. In recent years, by using algorithms based on a tensor network contraction framework, a series of simulations of a quantum circuit are implemented in products of various companies.

### SUMMARY

A quantum circuit simulation method and device, an apparatus, and a storage medium are provided according to the present application.

According to an aspect of the present application, a quantum circuit simulation method is provided. The method includes:

obtaining, based on a quantum circuit containing n qubits, an n-order pure state corresponding to the quantum circuit, the n-order pure state being represented by an n-order state tensor;

determining, based on the quantum circuit, a (k, k)-order gate tensor representing a quantum gate, on which a contraction processing is to be performed with the n-order state tensor, wherein k denotes an amount of qubits on which the quantum gate acts;

transforming the contraction processing between the n-order state tensor and the (k, k)-order gate tensor into a processing between matrices which can be expressed in a classic computer and reduce a computation amount in the classic computer, to obtain a processing result; and

using the processing result as a result of the contraction processing between the n-order state tensor and the (k, k)-order gate tensor, to complete simulation of the quantum circuit.

According to another aspect of the present application, a quantum circuit simulation device is provided. The device includes:

a state tensor obtaining unit, configured to obtain, based on a quantum circuit containing n qubits, an n-order pure state corresponding to the quantum circuit, the n-order pure state being represented by an n-order state tensor;

a gate tensor obtaining unit, configured to determine, based on the quantum circuit, a (k, k)-order gate tensor representing a quantum gate, on which a contraction processing is to be performed with the n-order state tensor, wherein k denotes an amount of qubits on which the quantum gate acts; and

a contraction processing unit, configured to transform the contraction processing between the n-order state tensor and the (k, k)-order gate tensor into a processing between matrices which can be expressed in a classic computer and reduce a computation amount in the classic computer, to obtain a processing result; and use the processing result as a result of the contraction processing between the n-order state tensor and the (k, k)-order gate tensor, to complete simulation of the quantum circuit.

According to yet another aspect of the present application, an electronic apparatus is provided. The electronic apparatus includes:

at least one processor; and

a memory communicatively connected to the at least one processor; wherein

the memory stores instructions executable by the at least one processor, the instructions are executed by the at least one processor to enable the at least one processor to perform a method described above.

According to yet another aspect of the present application, it is provided a non-transitory computer readable storage medium for storing computer instructions, wherein the computer instructions, when executed by a computer, cause the computer to implement a method described above.

It should be understood that the content described herein is not intended to denote key or critical elements of embodiments of the present application nor to limit the scope of the present application. Further features of the present application may be readily understood from the following description.

### BRIEF DESCRIPTION OF THE DRAWINGS

The drawings are used to better understand the scheme and do not constitute a limitation to the present application, wherein:

FIG. 1 is a schematic flow chart showing an implementation of a quantum circuit simulation method according to an embodiment of the present application;

FIG. 2 is a schematic flow chart showing a specific example of a quantum circuit simulation method according to an embodiment of the present application;

FIG. 3 is a schematic diagram showing a quantum circuit in a specific example according to an embodiment of the present application;

FIG. 4 is a schematic diagram showing a quantum circuit in a specific example according to an embodiment of the present application;

FIG. 5 is a schematic structural diagram showing a quantum circuit simulation device according to an embodiment of the present application;

FIG. 6 is a schematic structural diagram showing a quantum circuit simulation device according to an embodiment of the present application; and

FIG. 7 is a block diagram showing an electronic apparatus used for implementing a quantum circuit simulation method according to an embodiment of the present application.

### DETAILED DESCRIPTION

The exemplary embodiments of the application will be described below in combination with drawings, including various details of the embodiments of the present application to facilitate understanding, which should be considered as exemplary only. Therefore, those of ordinary skill in the art should realize that various changes and modifications can be made to the embodiments described herein without departing from the scope and spirit of the present application. Likewise, descriptions of well-known functions and structures are omitted in the following description for clarity and conciseness.

Here, the concept of tensor network is introduced first. Specifically, a tensor is mathematically defined as a multiple linear mapping in a vector space, which is equivalent to an n-dimensional array in computer science, i.e., an n-order tensor may be denoted as an n-dimensional array Tᵢ_{₁}ᵢ_{₂}_{. . . i}_{ₙ}. As to a tensor network, it is a set of finite or infinite tensors connected together. Concepts such as states and gates in a quantum circuit may all be expressed as tensors. Therefore, a quantum circuit may be expressed as a tensor network.

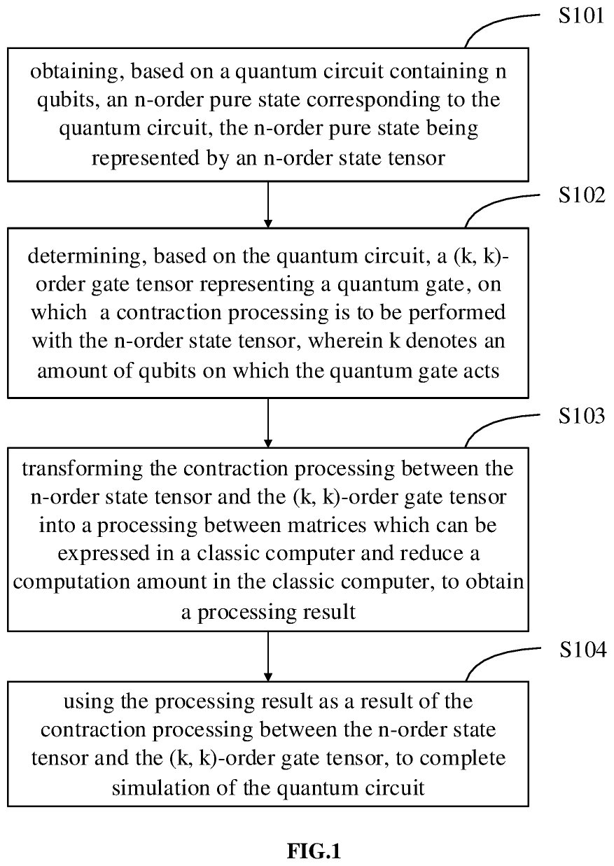

Specifically, FIG. 1 is a schematic flow chart showing an implementation of a quantum circuit simulation method according to an embodiment of the present application. As shown in FIG. 1, the method includes:

S101: obtaining, based on a quantum circuit containing n qubits, an n-order pure state corresponding to the quantum circuit, the n-order pure state being represented by an n-order state tensor;

S102: determining, based on the quantum circuit, a (k, k)-order gate tensor representing a quantum gate, on which a contraction processing is to be performed with the n-order state tensor, wherein k denotes an amount of qubits on which the quantum gate acts;

S103: transforming the contraction processing between the n-order state tensor and the (k, k)-order gate tensor into a processing between matrices which can be expressed in a classic computer and reduce a computation amount in the classic computer, to obtain a processing result; and

S104: using the processing result as a result of the contraction processing between the n-order state tensor and the (k, k)-order gate tensor, to complete simulation of the quantum circuit.

In practical applications, n is a positive integer larger than or equal to 2, and k is a positive integer smaller than or equal to n. Here, a quantum gate acts on k qubits in a quantum circuit, which may also be referred to as the quantum gate acts on k circuits in the quantum circuit, where each circuit corresponds to a qubit.

Here, the (k, k)-order gate tensor represents a quantum gate having k inputs and k outputs. In this example, the case where the number of inputs and outputs of a quantum gate are different is ignored.

In this way, by transforming a tensor contraction processing between a quantum gate and a pure state in a quantum circuit into a processing between matrices which may be expressed in a classic computer and reduce a computation amount in the classic compute, that is, by performing an isomorphic transformation of a tensor into a special kind of matrices and performing an isomorphic transformation of a tensor network contraction to an operation on matrices, the tensor network contraction is equivalently transformed into a matrix operation that may be directly executed in a computer device. Thus, computation steps are simplified, and computation efficiency and convenience are improved, thereby laying a foundation for an overall improvement of the efficiency of quantum circuit simulation.

In a specific example according to a scheme of the present application, the (k, k)-order gate tensor is represented by a gate matrix, the gate matrix being represented by a D^{k}×D^{k} unitary matrix, D being a dimension of energy levels of the qubits. In this way, a specific matrix expression for a gate tensor is provided, and the matrix expression may be conveniently expressed and processed in a classic computer, thereby laying a foundation for simplifying computation steps and improving computation efficiency.

In a specific example according to a scheme of the present application, the (k, k)-order gate tensor is represented by a gate matrix, the gate matrix being represented by a 2^{k}×2^{k} unitary matrix, in a case that the energy levels of the qubits are of 2-order (generally, energy levels of qubits of 2-order are commonly used superconductor and nuclear magnetic resonance (NMR) quantum computer energy levels); a rule of mapping various indices (i.e., various elements) in the (k, k)-order gate tensor to row indices and column indices (i.e., various elements) of the 2^{k}×2^{k} unitary matrix includes: qubits corresponding to k inputs of the (k, k)-order gate tensor are mapped to the column indices of the 2^{k}×2^{k} unitary matrix in a natural ranking order of qubit computational basis, and qubits corresponding to k outputs of the (k, k)-order gate tensor are mapped to the row indices of the 2^{k}×2^{k} unitary matrix in the natural ranking order of qubit computational basis. In this way, a corresponding gate matrix representing a k-order gate tensor is obtained. Evidently, this way is simple and convenient, and has high interpretability, while a foundation is laid for simplifying computation steps and improving computation efficiency. In addition, a foundation is further laid for an overall improvement of the efficiency of quantum circuit simulation.

In a specific example according to a scheme of the present application, the following way may be adopted to transform the contraction processing between the n-order state tensor and the (k, k)-order gate tensor into the processing between the matrices which can be expressed in the classic computer and reduce the computation amount in the classic computer, which specifically including:

performing, based on the k qubits on which the quantum gate acts, an axis-shifting transformation on the n-order state tensor, to move the k qubits on which the quantum gate acts to first k qubits of the quantum circuit, to obtain a (k, (n−k))-order state tensor; and transforming a contraction processing between the (k, (n−k))-order state tensor and the (k, k)-order gate tensor into a processing between a state matrix and a gate matrix which can be expressed in the classic computer and reduce the computation amount in the classic computer, wherein the (k, (n−k))-order state tensor is represented by the state matrix, and the (k, k)-order gate tensor is represented by the gate matrix. Here, in this example, the (k, k)-order gate tensor is represented by a gate matrix, and the gate matrix is represented by a D^{k}×D^{k} unitary matrix. Alternately, the gate matrix is represented by a 2^{k}×2^{k} unitary matrix.

That is to say, in the present example, an axis-shifting processing is performed on the n-order state tensor, and then a contraction processing is performed on the (k, (n−k))-order state tensor obtained after the axis-shifting processing and the (k, k)-order gate tensor, that is, the contraction processing between the (k, (n−k))-order state tensor and the (k, k)-order gate tensor is transformed into an operation processing between a state matrix and a gate matrix which may be expressed in a classic computer and reduce computation amount in the classic computer. Thus, a foundation is laid for effectively performing a multiplication operation. In addition, this way is simple and convenient, and has high interpretability, while a foundation is laid for simplifying computation steps and improving computation efficiency. In addition, a foundation is further laid for an overall improvement of the efficiency of quantum circuit simulation.

In a specific example according to a scheme of the present application, the state matrix is represented by a D^{k}×D^{n-k} matrix, D being a dimension of energy levels of the qubits. Thus, a specific matrix expression for a state tensor is provided, and the matrix expression may be conveniently expressed and processed in a classic computer, thereby laying a foundation for simplifying computation steps and improving computation efficiency.

In a specific example according to a scheme of the present application, in a case that the energy levels of the qubits are of 2-order, the state matrix is represented by a 2^{k}×2^{n-k} matrix; a rule of mapping various indices (i.e., various elements) in the (k, (n−k))-order state tensor to row indices and column indices (i.e., various elements) of the 2^{k}×2^{n-k} matrix includes: first k qubits of the (k, (n−k))-order state tensor are mapped to the row indices of the 2^{k}×2^{n-k} matrix in a natural ranking order of qubit computational basis, and last n-k qubits of the (k, (n−k))-order state tensor are mapped to the column indices of the 2^{k}×2^{n-k} matrix in the natural ranking order of qubit computational basis. In this way, a corresponding state matrix representing a (k, (n−k))-order state tensor is obtained. Evidently, this way is simple and convenient, and has high interpretability, while a foundation is laid for simplifying computation steps and improving computation efficiency. In addition, a foundation is further laid for an overall improvement of the efficiency of quantum circuit simulation.

In a specific example according to a scheme of the present application, the processing result is an updated state matrix obtained by performing a right multiplication on the gate matrix and the state matrix. For example, a right multiplication is performed on a gate matrix corresponding to a (k, k)-order gate tensor and a state matrix corresponding to a (k, (n−k))-order state tensor, which is obtained after an axis-shifting transformation of an n-order state tensor, such as 2^{k}×2^{k} unitary matrix×2^{k}×2^{n-k} matrix, to obtain an updated state matrix. This updated state matrix is then the processing result. Evidently, this process is simple and has high computation efficiency, thereby laying a foundation for an overall improvement of the efficiency of quantum circuit simulation.

In practical applications, the processing result may directly serve as the contraction processing result. Of course, the contraction processing result may also be transformed into a new tensor, which then serves as the contraction processing result, thereby facilitating further tensor contraction output. In a specific example according to a scheme of the present application, after obtaining a processing result, i.e., an updated state matrix, the updated state matrix is mapped into an updated tensor based on a mapping rule (similar to the aforementioned mapping rule of mapping a state tensor into a matrix); and based on the axis-shifting transformation, a reverse axis-shifting is performed on the updated tensor, in other words, a reverse processing is performed on the aforementioned axis-shifting processing and the axis is moved to the original position of the quantum circuit. Thus, a new n-order tensor which matches the qubits in the quantum circuit is obtained. Therefore, a foundation is laid for subsequent further tensor contraction processing, while a foundation is also laid for achieving the completion of quantum simulation computation.

According to a scheme of the present application, by transforming a tensor contraction processing between a quantum gate and a pure state in a quantum circuit into a processing between matrices which may be expressed in a classic computer and reduce a computation amount in the classic computer, the algorithms for computing tensor contraction are improved. Further, the improved scheme has high computation efficiency. In this way, the performance of quantum circuit simulation computation is improved, while a more efficient Einstein summation convention computation is realized.

In the following, the scheme of the present application is described further in detail in connection with specific examples. Specifically, in the present examples, an isomorphic transformation of the contraction of a tensor network of a quantum circuit into a matrix product is performed. Here, as the contraction of a tensor network corresponding to a quantum circuit occurs between a quantum gate and a pure state, it suffices to provide a corresponding tensor contraction between one quantum gate and one pure state, for performing an isomorphic transformation into a matrix product.

For example, it is assumed that a pure state in a quantum circuit containing n qubits (n-qubit quantum circuit) corresponds to an n-order tensor (hereinafter referred to as a state tensor), and a quantum gate which acts on k qubit circuits (i.e., k qubits) in the quantum circuit corresponds to a (k, k)-order tensor (hereinafter referred to as a gate tensor). Here, taking the energy levels of qubits are as an example of the 2-order, in this case, an isomorphic transformation of the contraction between the above two tensors into an operation of multiplication between a 2^{k}×2^{k} matrix and a 2^{k}×2^{n-k} matrix may be performed.

Specifically, it is as follows.

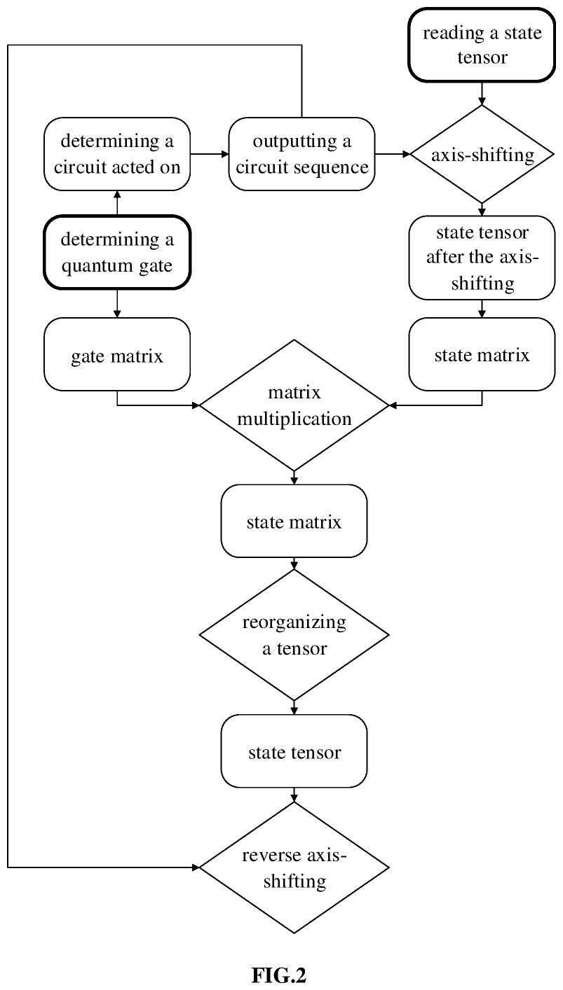

(I) As shown in FIG. 2, the scheme of isomorphic transformation of a tensor contraction between a quantum gate and a pure state into a matrix product includes the following steps.

Firstly, a state tensor is read, and an axis-shifting transformation on the state tensor is performed, so that an isomorphic transformation of an n-order state tensor into a 2^{k}×2^{n-k} state matrix is performed. The specific steps include shifting axes firstly, and then mapping. It is as follows.

(1) Qubit circuits to be acted on by a quantum gate is determined, to obtain an output circuit sequence, such as [m₁, m₂, . . . , mₖ]th circuit.

(2) An axis-shifting transformation on a state tensor is performed, with the objective of moving the k-qubit circuits to be acted on by the quantum gate to the positions of the [1, 2, . . . , k]th circuits, to facilitate a subsequent multiplication operation.

(3) A state tensor obtained after the axis-shifting transformation is made to correspond to a 2^{k}×2^{n-k} matrix. Here, a rule of mapping various indices in the state tensor obtained after the axis-shifting transformation to the row indices and column indices of the 2^{k}×2^{n-k} matrix is: the first k qubits of the state tensor obtained after the axis-shifting transformation are made to correspond to the row order of the matrix in a natural ranking order of qubit computational basis, and the last n-k qubits are made to correspond to the column order of the matrix in the natural ranking order of qubit computational basis.

Secondly, a (k, k)-order gate tensor is made to correspond to a 2^{k}×2^{k} unitary matrix. The objective is to perform a right multiplication on the unitary matrix and the state matrix obtained above, i.e., the 2^{k}×2^{n-k} matrix, to obtain a new state matrix. Here, the gate tensor is of the (k, k)-order, and the difference between inputs and outputs of the order of the gate tensor is ignored, i.e., it is assumed that the order of inputs and the order of outputs of a gate tensor are the same.

Here, the rule of mapping various indices in the gate tensor to the row indices and column indices of the 2^{k}×2^{k} unitary matrix is: the qubits corresponding to the k inputs in the (k, k)-order gate tensor correspond to the column order of the matrix in a natural ranking order of qubit computational basis, and the qubits corresponding to the k outputs correspond to the row order in the natural ranking order of qubit computational basis.

At last, the gate matrix 2^{k}×2^{k} is made to act on the state matrix 2^{k}×2^{n-k}, to obtain a new state matrix, and then a restoration processing is performed on the new state matrix, to obtain a new n-order state tensor. The restoration process includes:

performing a right multiplication on the 2^{k}×2^{k} gate matrix and the 2^{k}×2^{n-k} state matrix, to obtain a new 2^{k}×2^{n-k} state matrix; after mapping the new 2^{k}×2^{n-k} state matrix into an n-order tensor, performing an axis-shifting processing (for example, performing a reverse axis-shifting based on the above output circuit sequence), and moving to the position corresponding to the original quantum circuit, i.e., returning to the original position, to obtain a new n-order state tensor, thereby achieving tensor contraction between a quantum gate and a pure state.

(II) The mathematical description of the way of tensor axis-shifting transformation according to a scheme of the present application is provided below. Specifically, it is as follows.

Assuming that there exists two tensors: Rᵢ_{₁}ᵢ_{₂}_{. . . i}_{ₙ} and Sⱼ_{₁}ⱼ_{₂}_{. . . j}_{ₘ}, the tensor contraction of these two tensors regarding index vectors (iₚ_{₁}, iₚ_{₂}, . . . , iₚ_{ₕ}) and (jₚ_{₁}, jₚ_{₂}, . . . , jₚ_{ₕ}) may be expressed as Formula (1):

$$T = {\sum }_{( {i}_{{p}_{1}} , {i}_{{p}_{2}} , … , {i}_{{p}_{h}} ) = ( {j}_{{p}_{1}} , {j}_{{p}_{2}} , … , {j}_{{p}_{h}} )} {R}_{{i}_{1} {i}_{2} … {i}_{n}} {S}_{{j}_{1} {j}_{2} … {j}_{m}} . \qquad Formula ( 1 )$$

Here, a new tensor is obtained by switching indices of the tensors, i.e.:

$${R}_{{i}_{1} {i}_{2} … {i}_{n}} = {R}_{{i}_{1} {i}_{2} … {i}_{{p}_{1} - 1} {i}_{{p}_{1} + 1} … {i}_{n} {i}_{{p}_{1}}} . \qquad Formula ( 2 )$$

The meaning of the above equal sign is: the value of an index vector (i₁, i₂, . . . , iₚ_{₁}₋₁, iₚ_{₁}, iₚ_{₁}₊₁, . . . , iₙ) is given, a same component, i.e., a same complex number is taken for the tensors on both, left and right, sides. Therefore, following Formula (3) and Formula (4) may be obtained:

$$\begin{matrix}{R}_{{i}_{1} {i}_{2} … {i}_{n}} = {R}_{{i}_{1} {i}_{2} … {i}_{n} {i}_{{p}_{1}} {i}_{{p}_{2}} … {i}_{{p}_{h}}} ; & Formula ( 3 ) \\ and & \\ {S}_{{j}_{1} {j}_{2} … {j}_{m}} = {R}_{{j}_{{p}_{1}} {j}_{{p}_{2}} … {j}_{{p}_{h}} {j}_{1} {j}_{2} … {j}_{n}} . & Formula ( 4 )\end{matrix}$$

Thus, Formula (1) is transformed to Formula (5):

$$T = {\sum }_{( {i}_{{p}_{1}} , {i}_{{p}_{2}} , … , {i}_{{p}_{h}} ) = ( {j}_{{p}_{1}} , {j}_{{p}_{2}} , … , {j}_{{p}_{h}} )} {R}_{{i}_{1} {i}_{2} … {i}_{n} {i}_{{p}_{1}} {i}_{{p}_{2}} … {i}_{{p}_{h}}} {S}_{{j}_{{p}_{1}} {j}_{{p}_{2}} … {j}_{{p}_{h}} {j}_{1} {j}_{2} … {j}_{m}} . \qquad ( 5 )$$

(iₚ_{₁}, iₚ_{₂}, iₚ_{ₕ}) is denoted as index I₀, remaining indices of R are denoted as I₁; and (jₚ_{₁}, jₚ_{₂}, . . . , jₚ_{ₕ}) is noted as index J₀, and remaining indices of S are denoted as J₁; then Formula (5) may also be expressed as Formula (6):

T=Σ_{I}_{₀}_{=J}_{₀}R_{I}_{₁}_{I}_{₀}S_{J}_{₀}_{J}_{₁} Formula (6);

or denoted as Formula (7):

T=Σ_{I}_{₀}R_{I}_{₁}_{I}_{₀}S_{I}_{₀}_{J}_{₁} Formula (7).

In this way, the notations are simplified.

(III) In the following, an algorithm implementation of the way of tensor axis-shifting transformation according to a scheme of the present application is provided. Specifically, it is as follows.

According to Formula (1), all indices of an input tensor may be directly expressed, and a computational operation is performed by using the einsum method of numpy. However, if starting from Formula (7), it is only required to perform a contraction of two 2-order tensors, where the contraction instruction (idx) may be denoted as:
‘ab bZ->aZ’.

In order to use such an instruction to calculate a general contraction of two n-order tensors, the following transformation is required. Firstly, n-order tensors, i.e., n-dimensional arrays, need to undergo an axis transformation, to be transformed from the forms corresponding to the left sides of Formula (3) and Formula (4) to the tensor forms corresponding to the right sides. During the transformation process, the method of “numpy.moveaxis” is used, to move certain axes (source_pos) of a tensor (state_backup) representing a quantum state to specified positions (target_pos):

state_backup = np.moveaxis(state_backup, source_pos, target_pos)
# the final task is to perform contraction of state_backup and
gate_matrix_backup.
# according to the storage form of an array representing a gate, it is not
required to perform an axis transformation on gate_matrix_backup.

(IV) In the following, an algorithm implementation of the way of transforming a tensor axis-shifting transformation to a matrix computation according to a scheme of the present application is provided. Specifically, it is as follows.

In order to apply the simple form in Formula (7) for calculation, the input n-order tensor (gate_matrix_backup) and m-order tensor (state_backup) are transformed into 2-order tensors using the reshape method:

state_new_shape = [2** len(bits), 2 ** (len(state_backup.shape) −
len(bits))]
state_backup = np.reshape(state_backup, state_new_shape)
gate_new_shape = [2 ** (len(gate_matrix_backup.shape) − len(bits)),
2 ** len(bits)]
gate_matrix_backup = np.reshape(gate_matrix_backup,
gate_new_shape)

Then, the computation in Formula (7) may be performed:

state_backup = np.einsum(‘Za,ac−>Zc’, gate_matrix_backup,
state_backup)

In this way, not only the form is concise, but also the time consumed for writing to and reading from a memory is reduced, so that the running time may generally be significantly reduced. Further, as such tensor contraction is equivalent to a matrix multiplication, during this step, an ordinary matrix multiplication, such as the numpy.matmul( ) function, may be used directly for calculation.

state_backup = np.matmul(gate_matrix_backup, state_backup)

In this way, time may be further saved, and computation accuracy is also improved.

(V) In the following, an example of the tensor network contraction of a CNOT gate circuit is provided. Specifically, it is as follows.

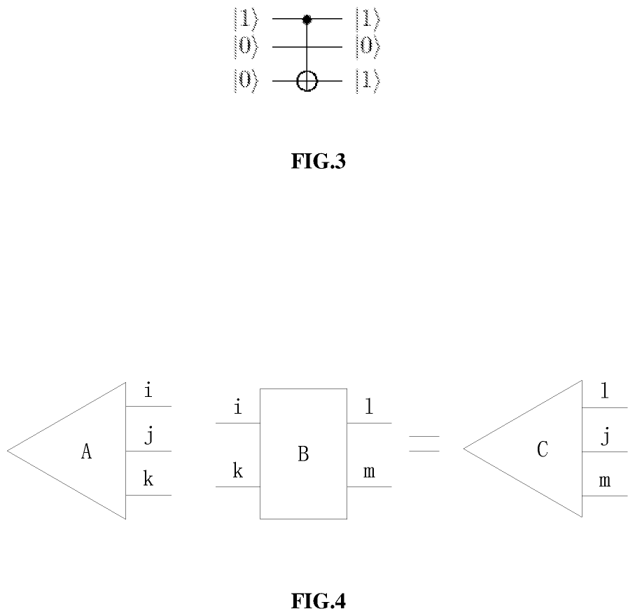

As shown in FIG. 3, the input state of a quantum circuit is |100 [symbol] , the output state is |101 [symbol] , and the quantum gate acts on circuits 1 and 3. Hereafter, the way of performing an isomorphic transformation of a tensor network contraction into a matrix product according to a scheme of the present application is provided.

Firstly, the input state |100 [symbol] is transformed to a matrix. As the CNOT gate acts on circuits 1 and 3, it is determined that qubits={1,3}. By applying the following steps, the input state is made to correspond to a 2²×2³⁻²=2²×2¹=4×2 matrix.

Specifically, the process includes:

(1) determining that the qubits to be acted on by the CNOT gate is the circuits 1 and 3;

(2) performing an axis-shifting transformation, to transforming the circuits 1 and 3 to be acted on by the gate to the positions of the circuits 1 and 2, specifically, it is as follows:
[0][0][0]=0→[0][0][0]=0
[0][0][1]=0→[0][1][0]=0
[0][1][0]=0→[0][0][1]=0
[0][1][1]=0→[0][1][1]=0
[1][0][0]=1→[1][0][0]=1
[1][0][1]=0→[1][1][0]=0
[1][1][0]=0→[1][0][1]=0
[1][1][1]=0→[1][1][1]=0;

(3) a state tensor obtained after performing the axis-shifting transformation is:
T=[[[0,0],[0,0]],[[1,0],[0,0]]];

according to a rule of mapping the indices of a tensor to the row indices and column indices of a matrix, the first 2 qubits of the above state tensor is mapped to correspond to the row indices of the matrix in a natural ranking order of computational basis, to obtain 00,01,10,11; and the last 1 qubit of the above new state tensor is mapped to correspond to the column indices of the matrix in the natural ranking order of computational basis, to obtain 0,1. Thus, the 4×2-order state matrix corresponding to the obtained new state tensor is:

$$[ \begin{matrix}{T}_{000} & {T}_{001} \\ {T}_{010} & {T}_{011} \\ {T}_{100} & {T}_{101} \\ {T}_{110} & {T}_{111}\end{matrix} ] = [ \begin{matrix}0 & 0 \\ 0 & 0 \\ 1 & 0 \\ 0 & 0\end{matrix} ] ;$$

where the matrix representation of the CNOT gate is

$$[ \begin{matrix}1 & 0 & 0 & 0 \\ 0 & 1 & 0 & 0 \\ 0 & 0 & 0 & 1 \\ 0 & 0 & 1 & 0\end{matrix} ] .$$

Here, the CNOT gate is made to act on an 4×2-order state matrix, i.e.:

$$[ \begin{matrix}1 & 0 & 0 & 0 \\ 0 & 1 & 0 & 0 \\ 0 & 0 & 0 & 1 \\ 0 & 0 & 1 & 0\end{matrix} ] [ \begin{matrix}0 & 0 \\ 0 & 0 \\ 1 & 0 \\ 0 & 0\end{matrix} ] = [ \begin{matrix}0 & 0 \\ 0 & 0 \\ 0 & 0 \\ 1 & 0\end{matrix} ] .$$

According to a rule of mapping the row indices and column indices of a matrix to indices of a tensor, the tensor indices representing various elements of a new 4×2-order state matrix is:

$$[ \begin{matrix}0 & 0 \\ 0 & 0 \\ 0 & 0 \\ 1 & 0\end{matrix} ] = [ \begin{matrix}{T}_{000} & {T}_{001} \\ {T}_{010} & {T}_{011} \\ {T}_{100} & {T}_{101} \\ {T}_{110} & {T}_{111}\end{matrix} ] .$$

Thus, a 3-order tensor transformed back from the new 4×2-order state matrix is:
T=[[[0,0],][0,0]],[[0,0],[1,0]]]

Then, the axes of the state tensor are shifted back to original positions. As the CNOT gate acts on the circuits 1 and 3, and the positions of the circuits 1 and 3 have been previously transformed to the positions of the circuits 1 and 2, here, the circuits 1 and 2 are transformed back to the positions of 1 and 3. The specific process is as follows:
[0][0][0]=0→[0][0][0]=0
[0][0][1]=0→[0][1][0]=0
[0][1][0]=0→[0][0][1]=0
[0][1][1]=0→[0][1][1]=0
[1][0][0]=0→[1][0][0]=0
[1][0][1]=0→[1][1][0]=1
[1][1][0]=1→[1][0][1]=0
[1][1][1]=0→[1][1][1]=0

A tensor obtained is: T′=[[[0,0],][0,0]], [[0,1], [0,0]]]. This tensor corresponds to the quantum state |101 [symbol] .

In this way, it is verified that the output matrix of the matrix product is consistent with the output state of the original quantum circuit. Thus, by applying the scheme of the present application, a simulation of a quantum circuit is realized.

(VI) In the following, testing results are provided.

Here, a result of performing contraction processing on the quantum circuit shown in FIG. 3 by using the existing einsum contraction method is provided firstly, which is as follows.

Einsum contraction (i.e., Einstein contraction summation, without axis-shifting transformation) scheme:

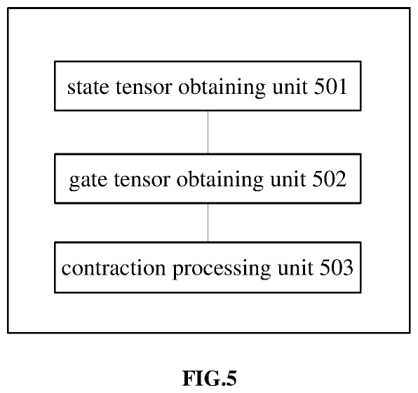

For convenience, following descriptions are provided. As shown in FIG. 4, an original state |100 [symbol] tensor is represented as: Aᵢⱼₖ, a CNOT gate tensor is represented as: Bᵢₖᵢₘ, a final state tensor is represented as: Cᵢⱼₘ. The einsum computation process (without an axis-shifting transformation) is as follows:

a tensor corresponding to |100 [symbol] is: [[[0,0],[0,0]],[[1,0],[0,0]]];

a tensor corresponding to the CNOT gate is:
[[[[1,0],[0,0]],[[0,1],[0,0]]],[[[0,0],[0,1]],[[0,0],[1,0]]]];

a tensor obtained after performing the einsum on CNOT and |100 [symbol] is: [[[0,0],[0,0]],[[0,1],[0,0]]], and the state corresponding to this tensor is: |101 [symbol] .

Then, an existing Bristlecone circuit is used for testing, and in the case of executing three different methods, the sum of the operation time of all tensor contractions in each circuit are recorded respectively, and then compared with each other. Here, electrical circuits with depths of 24, 32, and 40 are used. For the cases of 12qubit and 16qubit, the first five electrical circuits are used, and each experiment is repeated three times. For the case of 24qubit, as the computation time is relatively longer, the first two electrical circuits are used, and each experiment is repeated twice. The files are marked as “qubit number_depth_circuit_number”.

TABLE 1

| | | axis- | axis- | | axis- | axis- | | axis- | axis- |
|---|---|---|---|---|---|---|---|---|---|
| file | original | shifting | shifting | original | shifting | shifting | original | shifting | shifting |
| mark | einsum | einsum | matmul | einsum | einsum | matmul | einsum | einsum | matmul |
| 12_24_0 | 0.0643 | 0.0242 | 0.0204 | 0.0657 | 0.0366 | 0.0303 | 0.0412 | 0.0207 | 0.0155 |
| 12_24_1 | 0.0452 | 0.0242 | 0.0185 | 0.0525 | 0.0262 | 0.0191 | 0.0503 | 0.0267 | 0.0209 |
| 12_24_2 | 0.0609 | 0.0315 | 0.0247 | 0.0593 | 0.0285 | 0.0228 | 0.0616 | 0.0334 | 0.0252 |
| 12_24_3 | 0.0599 | 0.0311 | 0.0237 | 0.0669 | 0.0367 | 0.0301 | 0.1107 | 0.041 | 0.0348 |
| 12_24_4 | 0.0534 | 0.0274 | 0.0213 | 0.0512 | 0.0253 | 0.0201 | 0.0521 | 0.0273 | 0.021 |
| 12_32_0 | 0.0573 | 0.028 | 0.0227 | 0.0773 | 0.0386 | 0.0298 | 0.0913 | 0.0479 | 0.0394 |
| 12_32_1 | 0.0734 | 0.0375 | 0.0293 | 0.0796 | 0.0408 | 0.0325 | 0.0779 | 0.0395 | 0.03 |
| 12_32_2 | 0.069 | 0.0352 | 0.0273 | 0.0728 | 0.0386 | 0.0292 | 0.0613 | 0.0283 | 0.022 |
| 12_32_3 | 0.0581 | 0.0291 | 0.0209 | 0.0637 | 0.0323 | 0.0253 | 0.0602 | 0.0317 | 0.0249 |
| 12_32_4 | 0.0683 | 0.0339 | 0.0278 | 0.0759 | 0.0417 | 0.0316 | 0.0729 | 0.0384 | 0.0298 |
| 12_40_0 | 0.0852 | 0.0427 | 0.0339 | 0.096 | 0.0482 | 0.0373 | 0.0966 | 0.0518 | 0.0408 |
| 12_40_1 | 0.0943 | 0.0484 | 0.0372 | 0.0857 | 0.0454 | 0.0343 | 0.0881 | 0.0436 | 0.0344 |
| 12_40_2 | 0.0774 | 0.0381 | 0.0317 | 0.0737 | 0.0378 | 0.0276 | 0.0719 | 0.0353 | 0.0279 |
| 12_40_3 | 0.0731 | 0.0372 | 0.0296 | 0.0731 | 0.0362 | 0.0275 | 0.0692 | 0.0357 | 0.0277 |
| 12_40_4 | 0.0727 | 0.0385 | 0.0272 | 0.0703 | 0.0362 | 0.0269 | 0.0695 | 0.0365 | 0.0277 |
| 16_24_0 | 0.6185 | 0.3471 | 0.205 | 0.6403 | 0.3664 | 0.1917 | 0.6239 | 0.3615 | 0.1967 |
| 16_24_1 | 0.6205 | 0.3628 | 0.197 | 0.613 | 0.3384 | 0.1887 | 0.6244 | 0.3458 | 0.1954 |
| 16_24_2 | 0.6133 | 0.3427 | 0.1833 | 0.6408 | 0.3635 | 0.2008 | 0.7012 | 0.416 | 0.2587 |
| 16_24_3 | 0.6403 | 0.3627 | 0.1947 | 0.6521 | 0.3462 | 0.2011 | 0.6338 | 0.3479 | 0.1946 |
| 16_24_4 | 0.5987 | 0.3589 | 0.2058 | 0.644 | 0.365 | 0.217 | 0.6337 | 0.366 | 0.2174 |
| 16_32_0 | 0.8169 | 0.465 | 0.2489 | 0.9429 | 0.557 | 0.3015 | 0.8182 | 0.4476 | 0.2695 |
| 16_32_1 | 0.8104 | 0.4693 | 0.2563 | 0.8204 | 0.4616 | 0.2503 | 0.7907 | 0.4515 | 0.2597 |
| 16_32_2 | 0.9133 | 0.5271 | 0.3084 | 0.8096 | 0.4774 | 0.2562 | 0.8342 | 0.472 | 0.2649 |
| 16_32_3 | 0.8304 | 0.451 | 0.2479 | 0.8017 | 0.4424 | 0.2494 | 0.8319 | 0.4623 | 0.248 |
| 16_32_4 | 0.8402 | 0.468 | 0.2698 | 0.8132 | 0.4628 | 0.2434 | 0.816 | 0.4536 | 0.2568 |
| 16_40_0 | 1.0064 | 0.553 | 0.2919 | 1.0055 | 0.5658 | 0.3108 | 1.0088 | 0.5802 | 0.312 |
| 16_40_1 | 1.0038 | 0.5499 | 0.3134 | 0.9876 | 0.5578 | 0.3219 | 1.0219 | 0.5707 | 0.3093 |
| 16_40_2 | 0.9962 | 0.5411 | 0.3041 | 1.0196 | 0.5532 | 0.2922 | 1.0079 | 0.5983 | 0.3246 |
| 16_40_3 | 0.9973 | 0.5712 | 0.3173 | 1.0026 | 0.5229 | 0.3018 | 1.0177 | 0.5439 | 0.2904 |
| 16_40_4 | 1.0325 | 0.5598 | 0.318 | 0.9874 | 0.559 | 0.3172 | 1.0294 | 0.5691 | 0.3089 |
| 24_24_0 | 190.2355 | 176.795 | 116.5688 | 189.5737 | 172.6162 | 112.0729 | | | |
| 24_24_1 | 189.0513 | 168.2155 | 107.2157 | 189.4271 | 168.7957 | 107.3832 | | | |
| 24_32_0 | 255.2045 | 238.1813 | 153.7404 | 252.9268 | 236.5878 | 154.3787 | | | |
| 24_32_1 | 250.078 | 233.1288 | 151.5227 | 250.8447 | 232.2437 | 148.5379 | | | |
| 24_40_0 | 308.8267 | 288.2872 | 186.1364 | 307.0938 | 287.1367 | 185.4926 | | | |
| 24_40_1 | 309.4139 | 286.8113 | 183.8995 | 310.0614 | 290.333 | 187.2003 | | | |
| file | original | axis- | axis- | original | axis- | axis- | original | axis- | axis- |
| mark | einsum | shifting | shifting | einsum | shifting | shifting | einsum | shifting | shifting |
| | | einsum | matmul | | einsum | matmul | | einsum | matmul |

In the following Table 2, a comparison list of the time used by applying following three methods is provided: the einsum method used in an axis-shifting transformation, and the matmul method used in an axis-shifting transformation according to the scheme of the present application, and the original einsum method.

TABLE 2

| number | | | | axis- | axis- |
|---|---|---|---|---|---|
| of | circuit | circuit | original | shifting | shifting |
| qubits | depth | number | einsum | einsum | matmul |
| 12 | 24 | 0 | 1 | 0.476 | 0.387 |
| 12 | 24 | 1 | 1 | 0.521 | 0.395 |
| 12 | 24 | 2 | 1 | 0.514 | 0.399 |
| 12 | 24 | 3 | 1 | 0.458 | 0.373 |
| 12 | 24 | 4 | 1 | 0.511 | 0.398 |
| 12 | 32 | 0 | 1 | 0.507 | 0.407 |
| 12 | 32 | 1 | 1 | 0.51 | 0.398 |
| 12 | 32 | 2 | 1 | 0.503 | 0.387 |
| 12 | 32 | 3 | 1 | 0.512 | 0.391 |
| 12 | 32 | 4 | 1 | 0.525 | 0.411 |
| 12 | 40 | 0 | 1 | 0.514 | 0.403 |
| 12 | 40 | 1 | 1 | 0.512 | 0.395 |
| 12 | 40 | 2 | 1 | 0.499 | 0.391 |
| 12 | 40 | 3 | 1 | 0.506 | 0.394 |
| 12 | 40 | 4 | 1 | 0.523 | 0.385 |
| 16 | 24 | 0 | 1 | 0.571 | 0.315 |
| 16 | 24 | 1 | 1 | 0.564 | 0.313 |
| 16 | 24 | 2 | 1 | 0.574 | 0.329 |
| 16 | 24 | 3 | 1 | 0.549 | 0.307 |
| 16 | 24 | 4 | 1 | 0.581 | 0.341 |
| 16 | 32 | 0 | 1 | 0.57 | 0.318 |
| 16 | 32 | 1 | 1 | 0.571 | 0.316 |
| 16 | 32 | 2 | 1 | 0.577 | 0.324 |
| 16 | 32 | 3 | 1 | 0.55 | 0.302 |
| 16 | 32 | 4 | 1 | 0.561 | 0.312 |
| 16 | 40 | 0 | 1 | 0.562 | 0.303 |
| 16 | 40 | 1 | 1 | 0.557 | 0.313 |
| 16 | 40 | 2 | 1 | 0.56 | 0.305 |
| 16 | 40 | 3 | 1 | 0.543 | 0.301 |
| 16 | 40 | 4 | 1 | 0.554 | 0.31 |
| 24 | 24 | 0 | 1 | 0.92 | 0.602 |
| 24 | 24 | 1 | 1 | 0.89 | 0.567 |
| 24 | 32 | 0 | 1 | 0.934 | 0.606 |
| 24 | 32 | 1 | 1 | 0.929 | 0.599 |
| 24 | 40 | 0 | 1 | 0.934 | 0.603 |
| 24 | 40 | 1 | 1 | 0.932 | 0.599 |

Considering that the longer the time used by an electrical circuit, the more significant the effect of improvement, the results of time used by different electrical circuits above with the same bit number, the same depth, are directly summed and then averaged, to obtain the following average relative time used.

TABLE 3

| number | | | axis- |
|---|---|---|---|
| of | circuit | original | shifting |
| qubits | depth | einsum | matmul |
| 12 | 24 | 0.492 | 0.389 |
| 12 | 32 | 0.511 | 0.399 |
| 12 | 40 | 0.511 | 0.394 |
| 16 | 24 | 0.568 | 0.321 |
| 16 | 32 | 0.566 | 0.315 |
| 16 | 40 | 0.555 | 0.306 |
| 24 | 24 | 0.905 | 0.585 |
| 24 | 32 | 0.932 | 0.603 |
| 24 | 40 | 0.933 | 0.601 |

In above testing, different quantum circuits with different sizes and different depths are used for testing, and the time used by applying the original einsum method, the einsum method used in an axis-shifting transformation according to a scheme of the present application, and the matmul method used in an axis-shifting transformation according to a scheme of the present application, are compared. Then, following conclusions are reached.

In the case where the number of qubits is relatively small, by applying the einsum algorithm in an axis-shifting transformation and the matmul algorithm in the axis-shifting transformation according to a scheme of the present application, the computation speed may be significantly improved.

With the increase in the number of qubits and the increase in computation density, relatively large advantages may still be obtained by applying the matmul method in the axis-shifting transformation according to a scheme of the present application.

Based on above, according to a scheme of the present application, it is realized that the contraction of a tensor network of a quantum circuit is expressed as a matrix product. Compared to existing schemes adopted by other quantum simulators, a tensor network is not required to be transformed into an undirected graph, and a graph simplification is not required to be performed according to a scheme of the present application. Therefore, the efficiency and practicality of a contraction scheme are significantly improved. In addition, the scheme of the present application has general applicability, may use existing tool libraries, and may be widely applied to all quantum circuit modelling experiments.

Of course, in practical applications, computation efficiency may be further increased by improving the matmul function of matrix multiplication. For example, the Math Kernel Library (MKL) may be directly used, to accelerate computation. In addition, a matrix sparse processing method may be applied. In the scheme of the present application, no limitation is made thereto.

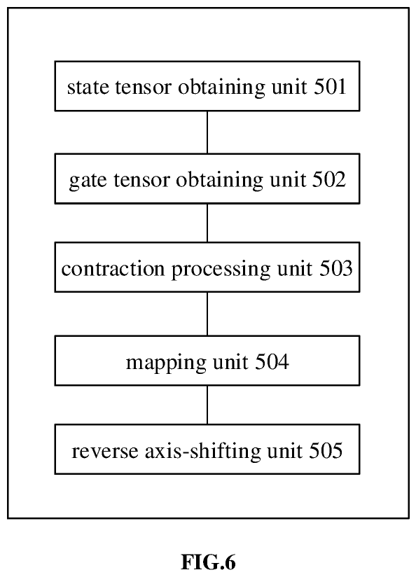

According to a scheme of the present application, a quantum circuit simulation device is provided. As shown in FIG. 5, the device includes:

a state tensor obtaining unit 501, configured to obtain, based on a quantum circuit containing n qubits, an n-order pure state corresponding to the quantum circuit, the n-order pure state being represented by an n-order state tensor;

a gate tensor obtaining unit 502, configured to determine, based on the quantum circuit, a (k, k)-order gate tensor representing a quantum gate, on which a contraction processing is to be performed with the n-order state tensor, wherein k denotes an amount of qubits on which the quantum gate acts; and

a contraction processing unit 503, configured to transform the contraction processing between the n-order state tensor and the (k, k)-order gate tensor into a processing between matrices which can be expressed in a classic computer and reduce a computation amount in the classic computer, to obtain a processing result; and use the processing result as a result of the contraction processing between the n-order state tensor and the (k, k)-order gate tensor, to complete simulation of the quantum circuit.

In a specific example according to a scheme of the present application, the (k, k)-order gate tensor is represented by a gate matrix, the gate matrix being represented by a D^{k}×D^{k} unitary matrix, D being a dimension of energy levels of the qubits.

In a specific example according to a scheme of the present application, the (k, k)-order gate tensor is represented by a gate matrix, the gate matrix being represented by a 2^{k}×2^{k} unitary matrix, in a case that the energy levels of the qubits are of 2-order;

a rule of mapping various indices in the (k, k)-order gate tensor to row indices and column indices of the 2^{k}×2^{k} unitary matrix includes: qubits corresponding to k inputs of the (k, k)-order gate tensor are mapped to the column indices of the 2^{k}×2^{k} unitary matrix in a natural ranking order of qubit computational basis, and qubits corresponding to k outputs of the (k, k)-order gate tensor are mapped to the row indices of the 2^{k}×2^{k} unitary matrix in the natural ranking order of qubit computational basis, to obtain a corresponding gate matrix representing a k-order gate tensor.

In a specific example according to a scheme of the present application, the contraction processing unit includes:

an axis-shifting processing sub-unit, configured to perform, based on the k qubits on which the quantum gate acts, an axis-shifting transformation on the n-order state tensor, to move the k qubits on which the quantum gate acts to first k qubits of the quantum circuit, to obtain a (k, (n−k))-order state tensor; and

a contraction processing sub-unit, configured to transform a contraction processing between the (k, (n−k))-order state tensor and the (k, k)-order gate tensor into a processing between a state matrix and a gate matrix which can be expressed in the classic computer and reduce the computation amount in the classic computer, wherein the (k, (n-k))-order state tensor is represented by the state matrix, and the (k, k)-order gate tensor is represented by the gate matrix.

In a specific example according to a scheme of the present application, the state matrix is represented by a D^{k}×D^{n-k} matrix, D being a dimension of energy levels of the qubits.

In a specific example according to a scheme of the present application, in a case that the energy levels of the qubits are of 2-order, the state matrix is represented by a 2^{k}×2^{n-k} matrix;

a rule of mapping various indices in the (k, (n−k))-order state tensor to row indices and column indices of the 2^{k}×2^{n-k} matrix includes: first k qubits of the (k, (n-k))-order state tensor are mapped to the row indices of the 2^{k}×2^{n-k} matrix in a natural ranking order of quibit computational basis, and last n-k qubits of the (k, (n−k))-order state tensor are mapped to the column indices of the 2^{k}×2^{n-k} matrix in the natural ranking order of qubit computational basis, to obtain a corresponding state matrix representing the (k, (n−k))-order state tensor.

In a specific example according to a scheme of the present application, the processing result is an updated state matrix obtained by performing a right multiplication on the gate matrix and the state matrix.

In a specific example according to a scheme of the present application, as shown in FIG. 6, the device further includes:

a mapping unit 504, configured to map, based on a mapping rule, the updated state matrix into an updated tensor; and

a reverse axis-shifting unit 505, configured to perform, based on the axis-shifting transformation, a reverse axis-shifting on the updated tensor, to obtain an updated n-order tensor matching the qubits in the quantum circuit.

It should be noted that descriptions of above device embodiments are similar to above method descriptions, and have the same beneficial effects as method embodiments, which are not repeated herein. For technical details not disclosed in embodiments of a device according to the present application, those skilled in the art should understand with reference to descriptions of embodiments of a method according to the present application. Detailed descriptions thereof are omitted here for conciseness.

According to an embodiment of the present application, an electronic apparatus and a readable storage medium are provided in the present application.

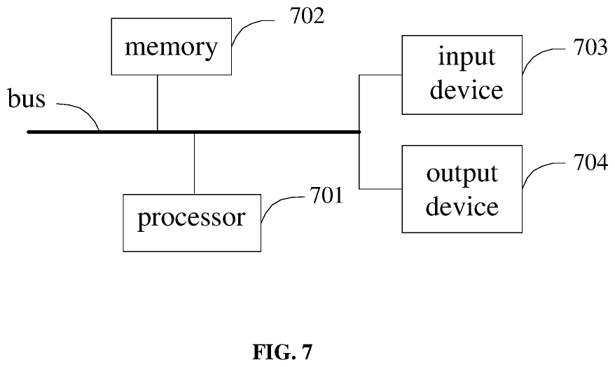

As shown in FIG. 7, it is a block diagram of an electronic apparatus for implementing a quantum circuit simulation method according to an embodiment of the present application. Electronic apparatuses are intended to represent various forms of digital computers, such as laptop computers, desktop computers, workbenches, personal digital assistants, servers, blade servers, mainframe computers, and other suitable computers. The components shown herein, their connections and relationships, and their functions are merely examples, and are not intended to limit the implementation of the present application described and/or claimed herein.

As shown in FIG. 7, the electronic apparatus includes: one or more processors 701, a memory 702, and interfaces for connecting various components, including a high-speed interface and a low-speed interface. The various components are connected to each other using different buses and may be installed on a common motherboard or installed in other ways as needed. The processor may process instructions executed within the electronic apparatus, including instructions which are stored in the memory or on the memory to display graphic information of a Graphical User Interface (GUI) on an external input/output device (such as a display apparatus coupled to the interface). In other embodiments, multiple processors and/or multiple buses may be used with multiple memories if desired. Similarly, multiple electronic apparatuses may be connected, and each apparatus provides a part of necessary operations, for example, as a server array, a group of blade servers, or a multi-processor system. In FIG. 7, one processor 701 is taken as an example.

The memory 702 is a non-transitory computer readable storage medium provided by embodiments of the present application. The memory stores instructions executable by at least one processor, so that the at least one processor executes the quantum circuit simulation method provided by embodiments of the present application. The non-transitory computer readable storage medium of an embodiment of the present application stores computer instructions, which are used to cause the computer to perform the quantum circuit simulation method provided by embodiments of the present application.

The memory 702, as a non-transitory computer readable storage medium, may be used to store non-transitory software programs, non-transitory computer executable programs and modules, such as program instructions/modules (for example, a state tensor obtaining unit 501, a gate tensor obtaining unit 502, a contraction processing unit 503, a mapping unit 504 and a reverse axis-shifting unit 505 shown in FIG. 6) corresponding to the quantum circuit simulation method in embodiments of the present application. The processor 701 executes various functional applications and data processing of the electronic apparatus executing the non-transitory software programs, instructions, and modules stored in the memory 702, that is, implements the quantum circuit simulation method in foregoing method embodiments.

The memory 702 may include a storage program area and a storage data area, where the storage program area may store an operating system and application programs required by at least one function, and the storage data area may store the data created according to the use of the electronic apparatus applied with a quantum circuit simulation method, etc. In addition, the memory 702 may include a high-speed random-access memory, and may also include a non-transitory memory, such as at least one magnetic disk storage device, a flash memory device, or other non-transitory solid-state storage devices. In some embodiments, the memory 702 may optionally include memories set remotely relative to the processor 701, and-these remote memories may be connected to the electronic apparatus for implementing a quantum circuit simulation method through a network. Instances of the above network include but are not limited to the Internet, an intranet, a local area network, a mobile communication network, and combinations thereof.

The electronic apparatus applied with a quantum circuit simulation method may further include: an input device 703 and an output device 704. The processor 701, the memory 702, the input device 703, and the output device 704 may be connected through a bus or in other ways. In FIG. 7, connection through a bus is taken as an example.

The input device 703, such as a touch screen, a keypad, a mouse, a trackpad, a touchpad, an indication rod, one or more mouse buttons, a trackball, a joystick, etc. may receive input numeric or character information, and generate key signal inputs related to user settings and function control of the electronic apparatus for implementing a quantum circuit simulation method. The output device 704 may include a display apparatus, an auxiliary lighting device and a tactile feedback device; wherein, the auxiliary lighting device is for example a Light Emitting Diode (LED); the tactile feedback device is for example a vibration motor, and the like. The display apparatus may include, but is not limited to, a liquid crystal display (LCD), an LED display, and a plasma display. In some embodiments, the display apparatus may be a touch screen.

Various embodiments of the systems and techniques described herein may be implemented in digital electronic circuit systems, integrated circuit systems, application specific integrated circuits (ASICs), computer hardware, firmware, software, and/or combination thereof. These various embodiments may include: implementations in one or more computer programs which may be executed and/or interpreted on a programmable system that includes at least one programmable processor, which may be a dedicated or general-purpose programmable processor that may receive data and instructions from a storage system, at least one input device, and at least one output device, and transmit the data and instructions to the storage system, the at least one input device, and the at least one output device.

These computer programs, also called as programs, software, software applications, or codes, include machine instructions of programmable processors, and these computer programs may be implemented using a high-level process and/or object-oriented programming language, and/or an assembly/machine language. As used herein, the terms “machine readable medium” and “computer readable medium” refer to any computer program product, apparatus, and/or device, for example, a magnetic disk, an optical disk, a memory, a programmable logic device (PLD), used to provide machine instructions and/or data to a programmable processor, including the machine readable medium that receives machine instructions as machine readable signals. The term “machine readable signal” refers to any signal used to provide machine instructions and/or data to the programmable processor.

In order to provide interactions with a user, the system and technology described herein may be implemented on a computer which has: a display device, for example a cathode ray tube (CRT) or an LCD monitor, for displaying information to the user; and a keyboard and pointing device, for example a mouse or a trackball, through which the user may provide input to the computer. Other kinds of devices may also be used to provide interactions with a user; for example, the feedback provided to a user may be any form of sensory feedback, for example, visual feedback, auditory feedback, or tactile feedback; and input from a user may be received using any form, including acoustic input, voice input, or tactile input.

The systems and techniques described herein may be implemented in a computing system (for example, as a data server) that includes back-end components, or be implemented in a computing system (for example, an application server) that includes middleware components, or be implemented in a computing system (for example, a user computer with a graphical user interface or a web browser through which the user may interact with the implementation of the systems and technologies described herein) that includes front-end components, or be implemented in a computing system that includes any combination of such back-end components, intermediate components, or front-end components. The components of the system may be interconnected by any form or medium of digital data communication, for example, a communication network. Examples of communication networks include a Local Area Network (LAN), a Wide Area Network (WAN), the Internet and a blockchain network.

The computer system may include a client and a server. The client and the server are generally remote from each other and typically interact through a communication network. The client-server relationship is generated by computer programs that run on respective computers and have a client-server relationship with each other. The server may be a cloud server, which is also referred to as a cloud computing server or a cloud host. The cloud server is a host product in a cloud computing service system, to solve the drawback existing in a classic physical host and virtual private server (VPS) service that management is hard and business scalability is poor.

According to the present application, by transforming a tensor contraction processing between a quantum gate and a pure state in a quantum circuit into a multiplication operation between matrices, computation steps are simplified, and computation efficiency is improved.

It should be understood that various forms of processes shown above may be used to reorder, add, or delete steps. For example, respective steps described in the present application may be executed in parallel, or may be executed sequentially, or may be executed in a different order, as long as the desired result of the technical solution disclosed in the present application can be achieved, no limitation is made herein.

The above specific embodiments do not constitute a limitation on the protection scope of the present application. It should be understood by those skilled in the art that various modifications, combinations, sub-combinations, and substitutions may be made according to design requirements and other factors. Any modification, equivalent replacement and improvement, and the like made within the spirit and principle of the present application shall be fall in the protection scope of the present application.

What is claimed is:

1. A quantum circuit simulation method, comprising:
obtaining, based on a quantum circuit containing n qubits, an n-order pure state corresponding to the quantum circuit, the n-order pure state being represented by an n-order state tensor;
determining, based on the quantum circuit, a (k, k)-order gate tensor representing a quantum gate, on which a contraction processing is to be performed with the n-order state tensor, wherein k denotes an amount of qubits on which the quantum gate acts;
transforming the contraction processing between the n-order state tensor and the (k, k)-order gate tensor into a processing between matrices which can be expressed in a classic computer and reduce a computation amount in the classic computer, to obtain a processing result; and
using the processing result as a result of the contraction processing between the n-order state tensor and the (k, k)-order gate tensor, to complete simulation of the quantum circuit.

2. The quantum circuit simulation method according to claim 1, wherein the (k, k)-order gate tensor is represented by a gate matrix, the gate matrix being represented by a D^{k}×D^{k} unitary matrix, D being a dimension of energy levels of the qubits.

3. The quantum circuit simulation method according to claim 1, wherein the (k, k)-order gate tensor is represented by a gate matrix, the gate matrix being represented by a 2^{k}×2^{k} unitary matrix, in a case that the energy levels of the qubits are of 2-order;
a rule of mapping various indices in the (k, k)-order gate tensor to row indices and column indices of the 2^{k}×2^{k} unitary matrix comprises: qubits corresponding to k inputs of the (k, k)-order gate tensor are mapped to the column indices of the 2^{k}×2^{k} unitary matrix in a natural ranking order of qubit computational basis, and qubits corresponding to k outputs of the (k, k)-order gate tensor are mapped to the row indices of the 2^{k}×2^{k} unitary matrix in the natural ranking order of qubit computational basis, to obtain a corresponding gate matrix representing a k-order gate tensor.

4. The quantum circuit simulation method according to claim 1, wherein the transforming the contraction processing between the n-order state tensor and the (k, k)-order gate tensor into the processing between the matrices which can be expressed in the classic computer and reduce the computation amount in the classic computer, comprises:
performing, based on the k qubits on which the quantum gate acts, an axis-shifting transformation on the n-order state tensor, to move the k qubits on which the quantum gate acts to first k qubits of the quantum circuit, to obtain a (k, (n−k))-order state tensor; and
transforming a contraction processing between the (k, (n−k))-order state tensor and the (k, k)-order gate tensor into a processing between a state matrix and a gate matrix which can be expressed in the classic computer and reduce the computation amount in the classic computer, wherein the (k, (n−k))-order state tensor is represented by the state matrix, and the (k, k)-order gate tensor is represented by the gate matrix.

5. The quantum circuit simulation method according to claim 2, wherein the transforming the contraction processing between the n-order state tensor and the (k, k)-order gate tensor into the processing between the matrices which can be expressed in the classic computer and reduce the computation amount in the classic computer, comprises:
performing, based on the k qubits on which the quantum gate acts, an axis-shifting transformation on the n-order state tensor, to move the k qubits on which the quantum gate acts to first k qubits of the quantum circuit, to obtain a (k, (n−k))-order state tensor; and
transforming a contraction processing between the (k, (n−k))-order state tensor and the (k, k)-order gate tensor into a processing between a state matrix and a gate matrix which can be expressed in the classic computer and reduce the computation amount in the classic computer, wherein the (k, (n−k))-order state tensor is represented by the state matrix, and the (k, k)-order gate tensor is represented by the gate matrix.

6. The quantum circuit simulation method according to claim 3, wherein the transforming the contraction processing between the n-order state tensor and the (k, k)-order gate tensor into the processing between the matrices which can be expressed in the classic computer and reduce the computation amount in the classic computer, comprises:
performing, based on the k qubits on which the quantum gate acts, an axis-shifting transformation on the n-order state tensor, to move the k qubits on which the quantum gate acts to first k qubits of the quantum circuit, to obtain a (k, (n−k))-order state tensor; and
transforming a contraction processing between the (k, (n−k))-order state tensor and the (k, k)-order gate tensor into a processing between a state matrix and a gate matrix which can be expressed in the classic computer and reduce the computation amount in the classic computer, wherein the (k, (n−k))-order state tensor is represented by the state matrix, and the (k, k)-order gate tensor is represented by the gate matrix.

7. The quantum circuit simulation method according to claim 4, wherein the state matrix is represented by a D^{k}×D^{n-k} matrix, D being a dimension of energy levels of the qubits.

8. The quantum circuit simulation method according to claim 4, wherein in a case that the energy levels of the qubits are of 2-order, the state matrix is represented by a 2^{k}×2^{n-k} matrix;
a rule of mapping various indices in the (k, (n−k))-order state tensor to row indices and column indices of the 2^{k}×2^{n-k} matrix comprises: first k qubits of the (k, (n−k))-order state tensor are mapped to the row indices of the 2^{k}×2^{n-k} matrix in a natural ranking order of quibit computational basis, and last n-k qubits of the (k, (n−k))-order state tensor are mapped to the column indices of the 2^{k}×2^{n-k} matrix in the natural ranking order of qubit computational basis, to obtain a corresponding state matrix representing the (k, (n−k))-order state tensor.

9. The quantum circuit simulation method according to claim 4, wherein the processing result is an updated state matrix obtained by performing a right multiplication on the gate matrix and the state matrix.

10. The quantum circuit simulation method according to claim 9, further comprising:
mapping, based on a mapping rule, the updated state matrix into an updated tensor; and
performing, based on the axis-shifting transformation, a reverse axis-shifting on the updated tensor, to obtain an updated n-order tensor matching the qubits in the quantum circuit.

11. A quantum circuit simulation device, comprising:
at least one processor; and
a memory communicatively connected to the at least one processor, wherein
the memory stores instructions executable by the at least one processor, the instructions are executed by the at least one processor to enable the at least one processor to:
obtain, based on a quantum circuit containing n qubits, an n-order pure state corresponding to the quantum circuit, the n-order pure state being represented by an n-order state tensor;
determine, based on the quantum circuit, a (k, k)-order gate tensor representing a quantum gate, on which a contraction processing is to be performed with the n-order state tensor, wherein k denotes an amount of qubits on which the quantum gate acts; and
transform the contraction processing between the n-order state tensor and the (k, k)-order gate tensor into a processing between matrices which can be expressed in a classic computer and reduce a computation amount in the classic computer, to obtain a processing result; and use the processing result as a result of the contraction processing between the n-order state tensor and the (k, k)-order gate tensor, to complete simulation of the quantum circuit.

12. The quantum circuit simulation device according to claim 11, wherein the (k, k)-order gate tensor is represented by a gate matrix, the gate matrix being represented by a D^{k}×D^{k} unitary matrix, D being a dimension of energy levels of the qubits.

13. The quantum circuit simulation device according to claim 11, wherein the (k, k)-order gate tensor is represented by a gate matrix, the gate matrix being represented by a 2^{k}×2^{k} unitary matrix, in a case that the energy levels of the qubits are of 2-order;
a rule of mapping various indices in the (k, k)-order gate tensor to row indices and column indices of the 2^{k}×2^{k} unitary matrix comprises: qubits corresponding to k inputs of the (k, k)-order gate tensor are mapped to the column indices of the 2^{k}×2^{k} unitary matrix in a natural ranking order of qubit computational basis, and qubits corresponding to k outputs of the (k, k)-order gate tensor are mapped to the row indices of the 2^{k}×2^{k} unitary matrix in the natural ranking order of qubit computational basis, to obtain a corresponding gate matrix representing a k-order gate tensor.

14. The quantum circuit simulation device according to claim 11, wherein the instructions are executed by the at least one processor to further enable the at least one processor to:
perform, based on the k qubits on which the quantum gate acts, an axis-shifting transformation on the n-order state tensor, to move the k qubits on which the quantum gate acts to first k qubits of the quantum circuit, to obtain a (k, (n−k))-order state tensor; and
transform a contraction processing between the (k, (n−k))-order state tensor and the (k, k)-order gate tensor into a processing between a state matrix and a gate matrix which can be expressed in the classic computer and reduce the computation amount in the classic computer, wherein the (k, (n−k))-order state tensor is represented by the state matrix, and the (k, k)-order gate tensor is represented by the gate matrix.

15. The quantum circuit simulation device according to claim 12, wherein the instructions are executed by the at least one processor to further enable the at least one processor to:
perform, based on the k qubits on which the quantum gate acts, an axis-shifting transformation on the n-order state tensor, to move the k qubits on which the quantum gate acts to first k qubits of the quantum circuit, to obtain a (k, (n−k))-order state tensor; and
transform a contraction processing between the (k, (n−k))-order state tensor and the (k, k)-order gate tensor into a processing between a state matrix and a gate matrix which can be expressed in the classic computer and reduce the computation amount in the classic computer, wherein the (k, (n−k))-order state tensor is represented by the state matrix, and the (k, k)-order gate tensor is represented by the gate matrix.

16. The quantum circuit simulation device according to claim 14, wherein the state matrix is represented by a D^{k}×D^{n-k} matrix, D being a dimension of energy levels of the qubits.

17. The quantum circuit simulation device according to claim 14, wherein in a case that the energy levels of the qubits are of 2-order, the state matrix is represented by a 2^{k}×2^{n-k} matrix;
a rule of mapping various indices in the (k, (n−k))-order state tensor to row indices and column indices of the 2^{k}×2^{n-k} matrix comprises: first k qubits of the (k, (n−k))-order state tensor are mapped to the row indices of the 2^{k}×2^{n-k} matrix in a natural ranking order of quibit computational basis, and last n-k qubits of the (k, (n−k))-order state tensor are mapped to the column indices of the 2^{k}×2^{n-k} matrix in the natural ranking order of qubit computational basis, to obtain a corresponding state matrix representing the (k, (n−k))-order state tensor.

18. The quantum circuit simulation device according to claim 14, wherein the processing result is an updated state matrix obtained by performing a right multiplication on the gate matrix and the state matrix.

19. The quantum circuit simulation device according to claim 18, wherein the instructions are executed by the at least one processor to further enable the at least one processor to:
map, based on a mapping rule, the updated state matrix into an updated tensor; and
perform, based on the axis-shifting transformation, a reverse axis-shifting on the updated tensor, to obtain an updated n-order tensor matching the qubits in the quantum circuit.

20. A non-transitory computer readable storage medium for storing computer instructions, wherein the computer instructions, when executed by a computer, cause the computer to:
obtain, based on a quantum circuit containing n qubits, an n-order pure state corresponding to the quantum circuit, the n-order pure state being represented by an n-order state tensor;
determine, based on the quantum circuit, a (k, k)-order gate tensor representing a quantum gate, on which a contraction processing is to be performed with the n-order state tensor, wherein k denotes an amount of qubits on which the quantum gate acts;
transform the contraction processing between the n-order state tensor and the (k, k)-order gate tensor into a processing between matrices which can be expressed in a classic computer and reduce a computation amount in the classic computer, to obtain a processing result; and
use the processing result as a result of the contraction processing between the n-order state tensor and the (k, k)-order gate tensor, to complete simulation of the quantum circuit.
